(19) United States
(12) Patent Application Publication
(10) Pub. No.: US 2005/0142817 A1
(43) Pub. Date: Jun. 30, 2005

(54) Surface planarization method of sequential lateral solidification crystallized poly-silicon thin film

(76) Inventors: Choong Yong Sohn, Chungcheongbuk-Do (KR); Yong Hae Kim, Kyeonggi-Do (KR); Jin Ho Lee, Daejeon-Shi (KR); Young Wook Ko, Daejeon-Shi (KR); Choong Heui Chung, Daejeon-Shi (KR); Chi Sun Hwang, Daejeon-Shi (KR); Yoon Ho Song, Daejeon-Shi (KR)

Correspondence Address: JACOBSON HOLMAN PLLC, 400 SEVENTH STREET N.W., SUITE 600, WASHINGTON, DC, 20004, US

(21) Appl. No.: 10/884,954

(22) Filed: Jul. 7, 2004

(30) Foreign Application Priority Data
Dec. 26, 2003 (KR) 2003-97258

(51) Int. Cl. C30B 1/00; H01L 21/20; H01L 21/36; H01L 21/26; H01L 21/42; H01L 21/324; H01L 21/477

(52) U.S. Cl. 438/486; 438/487; 438/795

(57) ABSTRACT

Provided is a method for planarizing a polysilicon surface grown by means of a sequential lateral solidification method, which comprises the steps of: crystallizing an amorphous silicon having a predetermined thickness formed on a substrate into the polysilicon layer by means of the sequential lateral solidification method; and planarizing the polysilicon layer by means of a laser having an energy density for converting partially melted polysilicon into fully melted polysilicon, so that electrical characteristics of element may be improved when the polysilicon thin film transistor is fabricated using the planarization process.

### BACKGROUND

1. Field of the Invention

The present invention relates to a surface planarization method for polysilicon crystallized by a sequential lateral solidification (SLS) method and, more particularly, to a method for improving performance of a switching element by using the planarized polysilicon as an active layer.

2. Discussion of Related Art

A polysilicon thin film transistor has high electric field characteristics and superior current driving capacity so that it is used for a circuit element of data, gate, and switching element for driving pixels of an active organic electroluminescent (EL) device or active liquid crystal display device (LCD).

In general, a thin film transistor using amorphous silicon as an active layer has an advantage that it may be processed with a simple process at a low temperature, however, has a disadvantage that it is difficult to apply it to a driving circuit operating at a high speed due to low electron mobility. In the meantime, when the polysilicon silicon is used as active layer, the number of the processes increases, however, the electron mobility becomes high to allow the driving circuit operating at a high speed to be fabricated. Such difference results from the fact that the polysilicon has a fine crystal structure to have a less number of defects than that of the amorphous silicon.

The method for crystallizing amorphous silicon into polysilicon includes a solidification crystallization method such as solid face crystallization (SPC) and metal induced crystallization (MIC) methods, and a liquid state crystallization method using a laser such as excimer laser annealing (ELA) and sequential lateral solidification (SLS) methods.

The SPS method crystallizes the amorphous silicon at a high temperature, so that the layer quality is good, however, it requires a high temperature process. The MIC method deposits a predetermined metal material on the amorphous silicon and applies heat thereon to perform crystallization, wherein the metal material acts to reduce enthalpy of the amorphous silicon to be crystallized, so that the crystallization process may be performed at a low temperature, however, the surface state is not good and element characteristics due to the metal are degraded when the element is fabricated.

The ELA and SLS methods employ a principle that the amorphous silicon is instantaneously (for example, for 30 nsec) melted by laser and then crystallized. The ELA method instantaneously supplies a laser energy to a substrate deposited by the amorphous silicon to allow the amorphous silicon to be melt and then cools it, so that the polysilicon is formed by means of silicon seed. The silicon seed acts as the amorphous silicon that is not melted by the laser. The SLS method fully melts the amorphous silicon exposed by the laser by means of a mask and then uses the amorphous silicon that is not exposed by the laser as a seed. Grains grow in a vertical direction at a boundary between a liquid state silicon region and a solid state silicon region, and it may be laterally grown with a predetermined length by properly adjusting an amount and an irradiation range of the laser energy.

Such SLS method may allow the thin film transistor having an active layer similar to a single crystal to be fabricated in accordance with a processing method, which leads to obtain field effect mobility exceeding 500 cm²/Vsec to the utmost, so that system on a display into which a driving circuit is integrated may be fabricated when the method is applied to an element operating at a high speed. Furthermore, this method may minimize the laser usage than the ELA method, which leads to improve process maintenance cost and productivity, which means that the SLS method is remarkably advantageous over the above-mentioned other methods.

The SLS process generally consists of two processes of an N-shot process and a 2-shot process in one field where the mask phase is formed on the amorphous silicon substrate in accordance with the number of sequential movement of the mask.

In accordance with the N-shot process, a ratio between a portion where laser is exposed by mask (hereinafter, it will be referred to as Line or L) and a portion where the laser is covered by the mask (hereinafter, it will be referred to as Space or S) may range from 1:2 up to 1:n, wherein the higher the n is, the longer the crystal becomes. When the length of the polysilicon laterally grown by one-shot irradiation of laser is typically about 2 um, a mask having a ratio of L/S=2/4 is employed. When the lateral grown length of the one shot irradiation is increased, the length may be increased to be an integer multiple of 2/4 to fabricate the mask.

### SUMMARY OF THE INVENTION

The present invention is directed to a method for planarizing an interface between a polysilicon layer and a gate oxidation layer and reducing a trap level to reduce the thickness of the gate oxidation layer, and for reducing a leak current of element to improve operating characteristics and reliability of the element.

One aspect of the present invention is to provide a method for planarizing a polysilicon surface grown by means of a sequential lateral solidification method, which comprises the steps of: crystallizing an amorphous silicon having a predetermined thickness formed on a substrate into the polysilicon layer by means of the sequential lateral solidification method; and planarizing the polysilicon layer by means of a laser having an energy density for converting partially melted polysilicon into fully melted polysilicon

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a schematic view of a process for forming a polysilicon crystal layer having a lateral grown length by means of a sequential lateral solidification method;

FIG. 2 shows an atomic force microscope (AFM) image, and a scanning electron microscope (SEM) picture obtained by experiment, in which surface roughness and space are inevitably occurred per each step of mask movement in the polysilicon formed by the process of FIG. 1;

FIG. 3 shows a graph of height of a surface roughness ridge based on the thickness of the amorphous silicon by means of AFM analysis, and height shapes of the surface roughness ridge to be occurred after crystallization when each thickness of the amorphous silicon is 500 Å and 2000 Å, respectively before crystallization;

FIG. 4 is a concept view for explaining a method for planarizing an SLS polysilicon layer crystallized by the n shot irradiation of laser as a planarization method in accordance with an embodiment of the present invention;

FIG. 5A shows a graph of root mean square (RMS) roughness value (Rrms) and height (Rp-v) of surface ridge measured by AFM analysis when the planarization process is performed in response to a change of laser energy density, and FIG. 5B shows SEM pictures resulted from crystallization shapes in response to the change of laser energy density of FIG. 5A;

FIG. 6 is a schematic view showing crystal grain shapes, cross section roughness and its space which are inevitably occurred in the SLS process when the sequential lateral crystallization is performed by the 2-shot process using the mask having a ratio of L/S=3/2 or 3/2.5;

FIG. 7 shows a case when a planarization process is performed for the 2-shot crystallized polysilicon.

FIG. 8A shows a resultant graph after a first planarization process is performed for the polysilicon which is already 2-shot crystallized, and FIG. 8B shows a graph of crystallized polysilicon by performing a second planarization process; and

FIG. 9 is a comparative result showing an improved ON/OFF characteristic in the case of thin film transistor after the planarization process is performed.

### DETAILED DESCRIPTION OF PREFERRED EMBODIMENTS

The present invention will now be described more fully hereinafter with reference to the accompanying drawings, in which preferred embodiments of the invention are shown.

### Embodiment

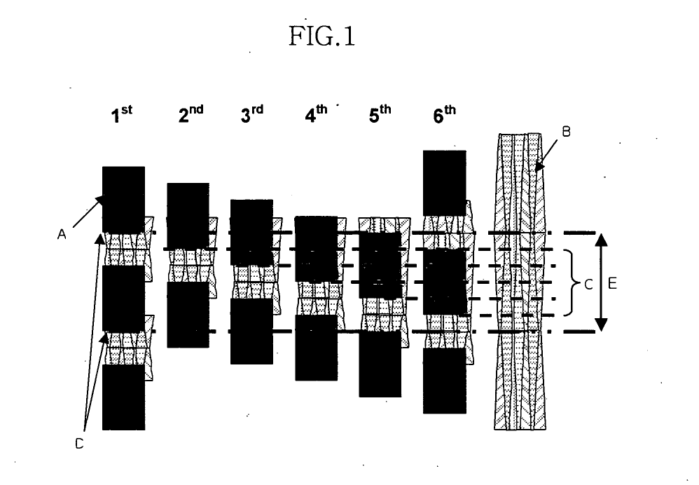

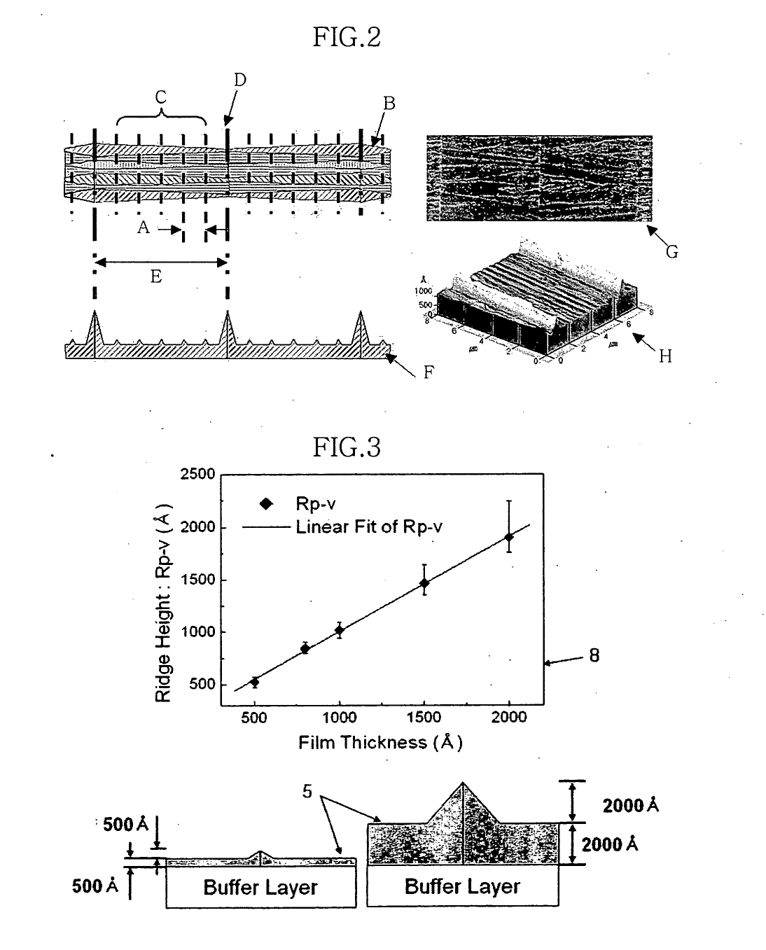

FIG. 1 shows a schematic process for obtaining polysilicon crystal having a lateral grown length of 6um by means of mask having a ratio of L/S=2/4 with 6-shot irradiation during an N-shot process, and FIG. 2 shows an atomic force microscope (AFM) image, and a scanning electron microscope (SEM) picture obtained by experiment, in which surface roughness and space are inevitably occurred per each step of mask movement in the polysilicon formed by the process of FIG. 1.

Referring to FIG. 1 and FIG. 2, A indicates a mask for SLS, B indicates a lateral crystal grown polysilicon, C indicates traces near edges occurred when the mask is moved during the SLS process, D indicates a grain boundary with which lateral grown crystal is met, E indicates a lateral grown length of 6 um by means of 6-shot irradiation, F indicates a cross section of the lateral crystal grown polysilicon, G indicates a surface SEM picture of the lateral crystal grown polysilicon, and H indicates an AFM image that has measured surface roughness of the lateral crystal grown polysilicon.

Silicon solution melted by the laser is solidified with crystal that has been grown in an opposite direction during the SLS process to form the grain boundary, and due to the volume movement and expansion to be occurred during the phase conversion from a liquid state to a solid state, the grain boundary is raised to form a ridge along the grain boundary surface, which causes the area of the grain boundary to be increased, and element characteristics of thin film transistors become degraded when the ridge height is increased because a trap level due to internal defects of the polysilicon is concentrated on the grain boundary surface.

Referring to FIG. 2, a mask with L/S=2/4 is used to have the grain boundary with 6 um space and the ridge through a 6-shot crystallization process, and small roughness of 1 um space same as a movement distance of the mask is occurred between the grain boundaries.

FIG. 3 shows a graph of ridge height based on the thickness of the amorphous silicon by means of AFM analysis, and height shapes of the surface roughness ridge to be occurred after crystallization when each thickness of the amorphous silicon is 500 Å and 2000 Å, respectively before crystallization.

The ridge-type surface roughness to be inevitably occurred in the SLS crystallization has a correlation with the thickness of the initial amorphous silicon, and it has been verified through experiments as shown in FIG. 2 that the surface roughness has direct proportion with the silicon thickness. The element characteristics of the SLS crystallization polysilicon thin film transistor are improved with the increasing thickness of the silicon, which results from the fact that the amount of volume to be melt by laser increases with the increasing thickness of the silicon to also increase the size of the lateral grown crystal. However, in accordance with the result of the present experiment, the more the thickness of the silicon increases, the height of the ridge-type surface roughness increases in direct proportion thereto, which leads to have adverse effects such as leak current increase, threshold voltage increase of the element or the like. Therefore, when the thickness of the amorphous silicon is constant, the ridge-type surface roughness may be reduced to fabricate the polysilicon thin film transistor which has reliable and superior characteristics.

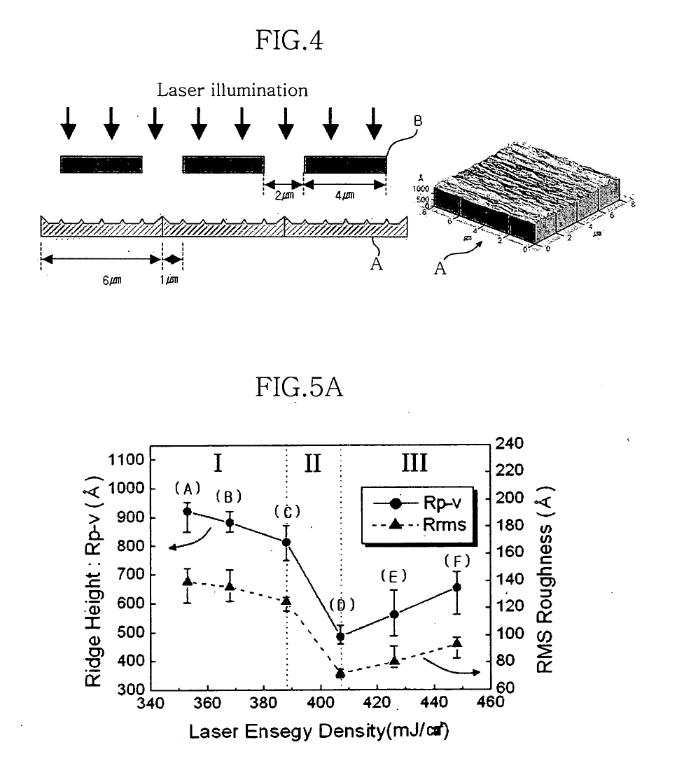

FIG. 4 shows a concept view for explaining a method for planarizing the SLS polysilicon layer in accordance with an embodiment of the present invention. An amorphous silicon layer is deposited on a substrate (which, for example, may be formed with a buffer material on a glass, silicon, and plastic), and is laterally crystallized by the N-shot crystallization method of FIG. 1 (it is crystallized by the 6-shot process using the mask with L/S=2/4 (B) in the present embodiment), the polysilicon (A) may be obtained to have a crystal size with 6 um space, ridge-type surface roughness with 6 um space, and low surface roughness between crystals with 1 um space, as mentioned above.

In this case, crystallized silicon is subject to planarization process using a laser having an energy density for converting the partial melting thereof to the full melting so as to planarize the SLS polysilicon layer in accordance with an embodiment of the present invention. FIG. 4 shows a view for performing planarization process using a mask with L/S=2/4 for surface planarization, and also shows the AFM analysis result that the polysilicon is planarized after the planarization process is performed, when the SLS process is performed using the same mask.

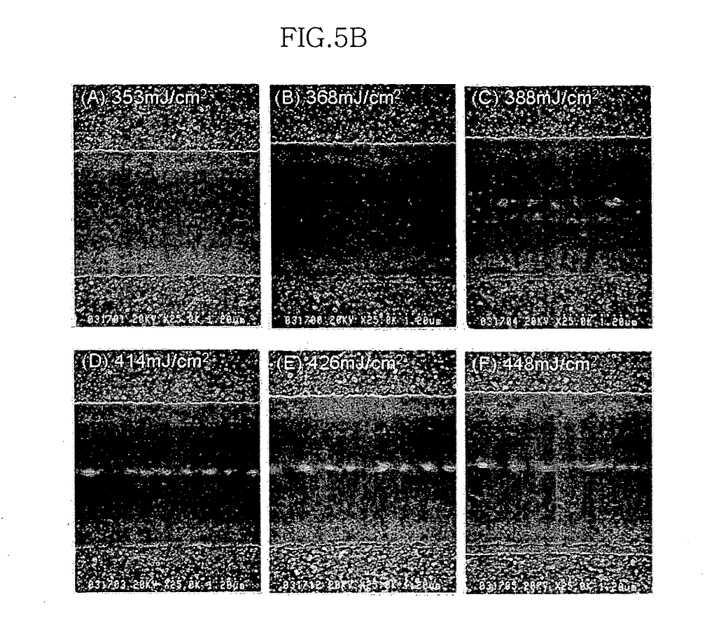

In the meantime, FIG. 5A shows a graph between surface ridge height (Rp-v) and root means square (RMS) roughness, which are measured through each AFM analysis when the planarization process is performed in response to the variation of the laser energy density (mJ/cm²) after the above-mentioned 6-shot crystallization process is performed while the thickness of the amorphous silicon is 800 Å. FIG. 5B shows SEM pictures of crystallization shape per sample in accordance with the variation of the laser energy density of FIG. 5A.

Referring to FIG. 5A and FIG. 5B, the variation of the surface roughness in accordance with the above-mentioned experimental results, is shown to have three zones. Zone I is shown between the sample A and the sample C, which has the gradually reduced surface roughness in response to the energy density increase. Zone II has the drastically reduced surface roughness between the sample C and the sample D, and zone III has the surface roughness to be increased again between the sample D and the sample F.

This result may be observed in the SEM analysis of FIG. 5B, wherein partial melting is occurred when the amorphous silicon is irradiated with the laser in the energy density section, namely, the zone I. The ridge having a relatively high thickness does not allow the full melting to be occurred with the energy of this section, so that a drastic height reduction is not occurred, however, the height is being reduced by the portion of partial melting. As can be seen, conversion from the partial melting to the full melting is performed in the zone II, which leads to start lateral crystallization by means of the full melting in the sample D. Full melting is performed in energy density of the zone III, wherein the melting portion is increased again by means of the energy density increase in a full melting state, so that the ridge height becomes increased by means of an increase of the total melting volume and an increase of resolidifying amount.

Therefore, the zone having an effective advantage of reducing the ridge height is seen to be a section where the conversion from the partial melting to the full melting is occurred. In particular, the value of the energy density capable of minimizing the ridge height is 414 mJ/cm² in accordance with the present experiment.

Table 1 shows the optimal section of the surface planarization laser energy density in accordance with the thickness of the amorphous silicon thin film. The optimal surface planarization energy is obtained by conducting experiment in response to the varied thickness of the amorphous silicon to have the energy density section where conversion from the partial melting to the full melting is occurred.

TABLE 1
definition of the surface planarization energy density zone in response
to the thickness range of the amorphous silicon thin film.

| Thickness of | Energy density of |
|---|---|
| amorphous silicon thin film | surface planarization |
| (Å) | (mJ/cm²) |
| 500 or less | 380 or less |
| 500˜800 | 320˜440 |
| 800˜1000 | 400˜480 |
| 1000˜1500 | 460˜620 |
| 1500˜2000 | 580˜760 |

Section values of the table 1 are defined when the given laser energy is converted and generalized to a density value of the energy per unit area with respect to the irradiation area. Therefore, when the crystallization and planarization processes are performed, values of the table 1 having generalized energy density value per unit area are not changed even when the mask space is varied, so that they may be applied to all cases.

In the meantime, when the planarization process is performed employing the above-mentioned surface planarization laser energy, effective mask structure is as follows. In accordance with the experiment, mask is not used when the polysilicon layer is planarized, and planarization phenomenon is not occurred when the planarization is performed over the entire surface with one shot irradiation at the above-mentioned energy densities. The reason is that the grain boundary where the ridge-type surface roughness is occurred has a thickness about two times thicker than other portion as shown in FIG. 3, and the melting volume when the entire region is irradiated with the laser is same in both the ridge portion and the planarization portion, so that the resolidifying phenomenon is also occurred uniformly over the entire region, which leads to have the same height between the ridge portion and the planarization portion. Therefore, superior planarization characteristics could be obtained only when the grain boundary of the polysilicon is irradiated with the laser by means of a predetermined mask in accordance with the present invention. Hereinafter, a preferred shape of the mask will be described in the cases when the N-shot crystallization method and 2-shot crystallization method are performed.

Case of N-Shot Crystallization

Referring to FIG. 4, when an amorphous silicon layer is deposited on a substrate and the amorphous silicon is laterally crystallized by means of the N-shot crystallization method, for example, when the 6-shot crystallization process is performed using a mask with L/S=2/4, laser may be irradiated in a manner to allow a portion having the ridge-type surface roughness of 6um space to be opened by means of the mask with L/S=2/4 same as that of the planarization process (see FIG. 4). In this case, the energy density of the laser to be irradiated is same as the above-mentioned description. When the crystallization process is performed using the mask with L/S=2/4, the surface roughness is formed per 6 um space, so that it is preferable to perform planarization using the mask with L/S=2/4 which allows the opened portion to be formed per 6 um space, and ridge roughness regions of all grain boundaries are not included when a mask having a different space is used.

In the meantime, when the space (S) is increased to have a ratio of L/S=2/(4+n, wherein n is natural number) of the mask for crystallization in order to increase the crystal length, the crystal length of the polysilicon and the ridge space have values of L+S. When the polysilicon is crystallized by the N-shot process, the mask for planarization may use the same mask as that for crystallization. In accordance with the experiment, the planarized polysilicon may be obtained after the planarization process as shown in FIG. 4A.

Case of 2-Shot Crystallization

Another method for forming the polysilicon by means of the SLS crystallization method includes the 2-shot process, wherein the mask for crystallization is one with L/S (L is greater than S), and L/S=3/2 or 3/2.5 is mainly used. The crystallized polysilicon is planarized by one or two shot laser irradiation in this case. When the crystal length is sufficiently long which may be laterally grown by one shot laser irradiation, it may be increased when each size of L and S is increased to have each integer multiple under the rule that L is greater than S in the ratio of L/S.

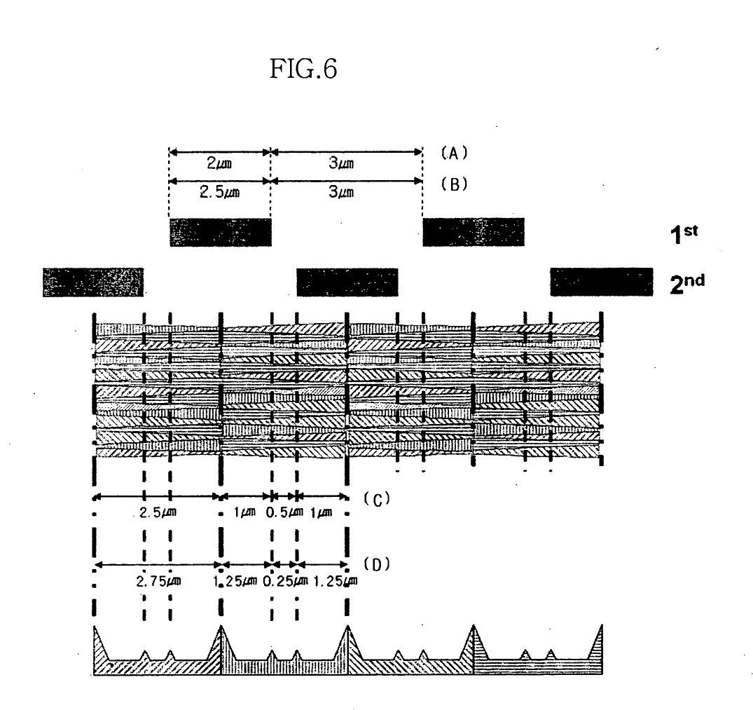

FIG. 6 shows a schematic view that includes crystal grain shapes, cross section roughness and its space which are inevitably occurred in the SLS process when the sequential lateral crystallization is performed by the 2-shot process using the mask having a ratio of L/S=3/2 or 3/2.5. (A), (B), (C), and (D) shown in FIG. 6 indicate a mask for crystallization with L/S=3/2 in the 2-shot crystallization process, a mask for crystallization with L/S=3/2.5 in the 2-shot crystallization process, a surface roughness space when the 2-shot lateral crystallization is performed using the mask with LIS=3/2, and a surface roughness space when the 2-shot lateral crystallization is performed using the mask with L/S=3/2.5, respectively. As shown in FIG. 6, when the second shot irradiation is applied after the mask is laterally moved by 2.5 um or 2.75 um after the first shot irradiation, polysilicon having respective lateral crystal lengths of 2.5 um and 2.75 um may be obtained, and the ridge-type surface roughness space is also formed to have respective 2.5 um and 2.75 um.

Next, a method for surface planarization capable of being performed will be described when such 2-shot crystallization method is used for the crystallization.

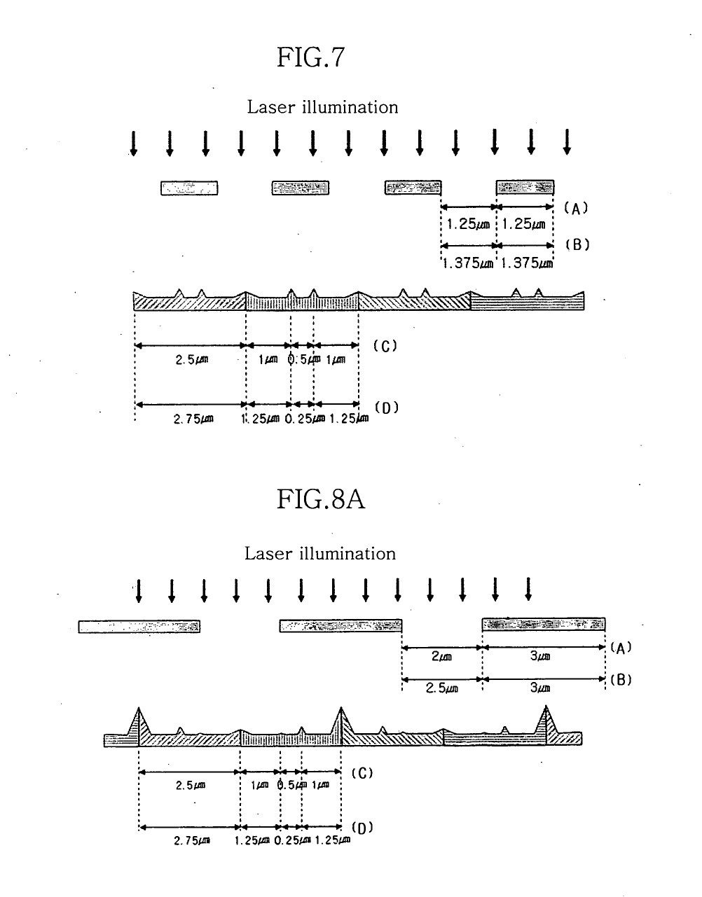

FIG. 7 shows a case when a planarization process is performed with one shot irradiation after crystallization is performed for the polysilicon using a 2-shot crystallization method. (A) and (B) of FIG. 7 show cases when the mask for planarization process has a ratio of L/S=1.25/1.25 and 1.375/1.375, respectively, and (C) and (D) show surface roughness spaces after 1-shot planarization using the mask for planarization process of (A) and (B).

Referring to FIG. 7, when the mask space for crystallization is set to be have a ratio of L/S (L is greater than S), a first method is to perform the planarization process one time, wherein the mask for planarization may be set to allow L and S to have the same space defined as n, so that the space n may be set to n=(L+S)/4. The above equation should be obeyed, which allows only surface roughness portions occurred when crystallization is performed to form an opened region, so that it is not possible to planarize using other type of mask. For example, the mask for planarization is designed to have 1.25/1.25 (when the mask with 3/2 is used for the crystallization) or 1.375/1.375 (when the mask with 3/2.5 is used for the crystallization), and the laser energy density shown in the table 1 is applied to perform the planarization process. Such planarization process may allow the polysilicon to have a smoothed ridge with one time. In addition, laser irradiation may be preferably performed to allow the portion having the ridge-type surface roughness to be opened (see FIG. 7).

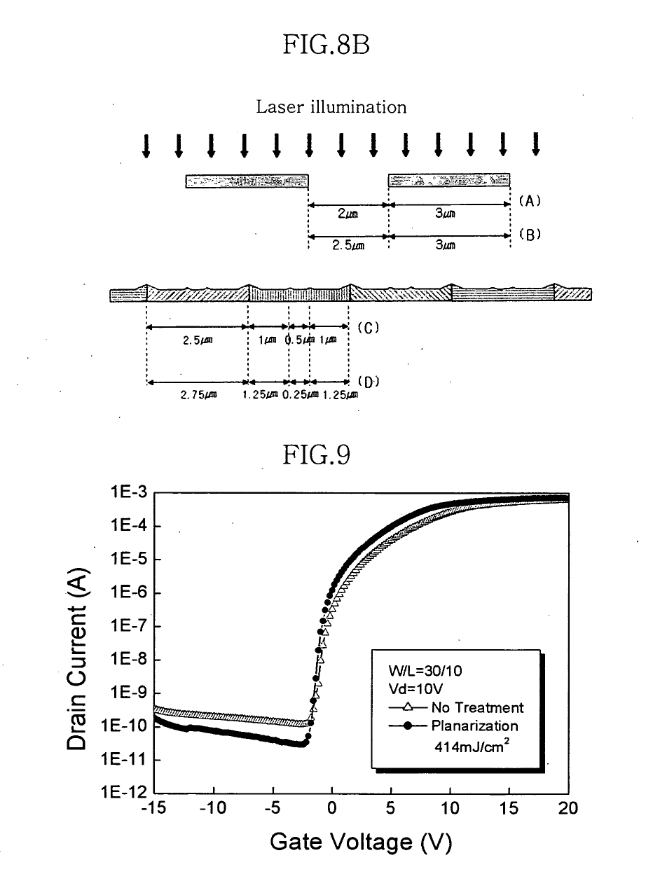

Referring to FIG. 8A and FIG. 8B, a second method may use the mask with S/L (which is the reverse ratio of L/S of the mask for crystallization) to perform planarization with the two shot laser irradiation shown in the table 1 when the mask for crystallization has a ratio of L/S (L is greater than S) for performing crystallization. The above-mentioned mask space for planarization may be opened by one per two ridge-type roughness portions occurred during the crystallization process and may generate opening in the remaining roughness portion when the laser moves by the same length as the grain space to be irradiated. When the space of S/L is not used, planarization by means of two shot laser irradiation process may be impossible. For example, the mask for planarization has 2/3 when the mask for crystallization has a ratio of L/S=3/2, and the mask for planarization has a ratio of 2.5/3 when the mask for crystallization has a ratio of L/S=3/2.5.

(A) of FIG. 8A shows a case that the mask for crystallization has a ratio of L/S=3/2 and the mask for planarization has a ratio of L/S=2/3, (B) of FIG. 8A shows a case that the mask for crystallization has a ratio of L/S=3/2.5 and the mask for planarization has a ratio of L/S=2.5/3, and (C) and (D) show surface roughness spaces after the first shot when the 2-shot planarization process is performed using the mask for (A) and (B) planarization, respectively. In the meantime, (A) of FIG. 8B shows a case that the mask for crystallization has a ratio of L/S=3/2 and the mask for planarization has a ratio of L/S=2/3, (B) of FIG. 8B a case shows that the mask for crystallization has a ratio of L/S=3/2.5 and the mask for planarization has a ratio of L/S=2.5/3, (C) and (D) show surface roughness spaces after the second shot when the 2-shot planarization process is performed using the mask for (A) and (B) planarization, respectively.

In accordance with the second method, the crystallized polysilicon may be planarized by performing the second planarization process as shown in FIG. 8B after the first planarization process is performed as shown in FIG. 8A. In addition, the laser may be irradiated to allow the portion having the ridge-type surface roughness to be opened (see FIG. 8A and 8B).

In accordance with the second method, the surface roughness trace occurred on the surface between crystals may also be planarized when the mask is moved, which is different from the first method. Because heat energy is conducted wider than the mask space to partially melt the portion having the surface roughness when the laser for planarization is irradiated.

In the meantime, the 2-shot process performs crystallization with two shot irradiation using the mask with L/S=3/2 or 3/2.5 when the length of laterally grown crystal by one shot laser irradiation is about 2 um. In this case, the mask for crystallization may be designed to allow the mask to have an integer multiple of L/S=3/2 or 3/2.5 when the grown length is increased with one shot laser irradiation. In other words, when the laterally grown length of the crystal with one shot laser irradiation is sufficiently long to exceed 2 um, the L/S ratio of the mask for crystallization may be increased to be the integer multiple of the above-mentioned value. Therefore, the mask for planarization is preferably adjusted in response to the above-mentioned adjustment.

### COMPARATIVE EXAMPLE

In accordance with the method of the present invention as mentioned above, the amorphous silicon layer having a thickness of 800 Å was SLS crystallized to form polysilicon, which was used as an active layer to fabricate the polylsilicon thin film transistor having the typical top gate structure. For comparison, under the same condition, two cases had been conducted, which consists of one that the crystallization process was performed and the planarization process was then performed (which has the laser energy of 414 mJ/cm²), and the other that these two processes were not performed, so that the drain current was measured in response to the applied gate voltage at the drain voltage of 10V (Vd). FIG. 9 shows a graph of experimental result of the comparative example. When the planarization process was performed for the thin film transistor, it could be seen that ON/OFF characteristics of the thin film transistor were improved.

The value of the leak current was shown to continuously decrease with the increasing laser energy density, however, the value of the sub-threshold swing had the minimum value at 414 mJ/cm² which is optimal planarization energy and increased again when the energy increased. This may be interpreted from the following description. The leak current and field effect mobility dependent on the shallow trap level were continuously decreased to have the minimum value of the leak current at the high laser energy because the strain bond was continuously decreased when the amount of laser energy was increased for the polysilicon during the planarization process, however the threshold voltage and the sub-threshold swing dependent on the deep trap level was determined by the amount of dangling bond concentrated on the grain boundary surface, so that the threshold voltage and the sub-threshold swing had the optimal value when the ridge height was the lowest, and the characteristics thereof were degraded due to the increase of the ridge height.

In accordance with embodiments of the present invention which applies the polysilicon to the thin film transistor, first, the height of the grain boundary ridge may be decreased to reduce the thickness of the gate oxidation layer, which leads to improve the element characteristic.

Second, the trap level due to internal defects of the polysilicon may be decreased to improve the element characteristic and fabricate the reliable element.

While the present invention has been described with reference to a particular embodiment, it is understood that the disclosure has been made for purpose of illustrating the invention by way of examples and is not limited to limit the scope of the invention. And one skilled in the art can make amend and change the present invention without departing from the scope and spirit of the invention.

1. A method for planarizing a crystallized polysilicon layer using a sequential lateral solidification (SLS) method, the method comprising the steps of:
crystallizing an amorphous silicon layer formed in a predetermined thickness on a substrate into the polysilicon layer using the sequential lateral solidification (SLS) method; and
planarizing the polysilicon layer using a laser having an energy density for converting partial melted polysilicon into full melted polysilicon.

2. The method as claimed in claim 1, wherein the energy density of surface planarization in response to the amorphous silicon layer has values shown in the table below.

| Thickness of | Energy density of |
|---|---|
| amorphous silicon thin film | surface planarization |
| (Å) | (mJ/cm²) |
| 500 or less | 380 or less |
| 500˜800 | 320˜440 |
| 800˜1000 | 400˜480 |
| 1000˜1500 | 460˜620 |
| 1500˜2000 | 580˜760 |

3. The method as claimed in claim 1, wherein only some portions of the polysilicon are irradiated with the laser by means of a mask for planarizing the polysilicon layer.

4. The method as claimed in claim 1, wherein the planarization is performed using a mask with L/S same as the mask for crystallization when the polysilicon layer is crystallized by means of an N-shot crystallization method.

5. The method as claimed in claim 4, wherein the mask for planarization employs a mask with L/S=2/4 when the mask for crystallization with L/S=2/4 is used to perform N-shot SLS crystallization.

6. The method as claimed in claim 1, wherein the mask for planarization performs the planarization process using 2-shot irradiation with an S/L ratio that is a reverse ratio of the mask for crystallization (L/S), or using 1-shot irradiation with a (L+S)/4 ratio in which each of the L and S has the same size, when the polysilicon layer is crystallized by a 2-shot crystallization method.

7. The method as claimed in claim 6, wherein the planarization process is performed with 1-shot laser irradiation using the mask for planarization with a ratio of 1.25/1.25 when the 2-shot crystallization is performed by the mask for crystallization with a ratio of L/S=3/2, or using the mask for planarization with a ratio of 1.75/1.75 when the 2-shot crystallization is performed by the mask for crystallization with a ratio of L/S=3/2.5.

8. The method as claimed in claim 6, wherein the planarization process is performed with 2-shot laser irradiation using the mask for planarization with a ratio of 2/3 when the 2-shot crystallization is performed by the mask for crystallization with a ratio of L/S=3/2, or using the mask for planarization with a ratio of 2.5/3 when the 2-shot crystallization is performed by the mask for crystallization with a ratio of L/S=3/2.5.
